(19) United States
(12) Patent Application Publication
(10) Pub. No.: US 2012/0229134 A1
(43) Pub. Date: Sep. 13, 2012

(54) CURRENT DETECTION DEVICE

(75) Inventor: Tatsuki ABE, Anjo-shi (JP)

(73) Assignee: AISIN AW CO., LTD., Anjo-shi (JP)

(21) Appl. No.: 13/367,703

(22) Filed: Feb. 7, 2012

(30) Foreign Application Priority Data
Mar. 11, 2011 (JP) 2011-054540

(51) Int. Cl. G01R 33/04

(52) U.S. Cl. 324/253

(57) ABSTRACT

A current detection device including a first sensor part and a second sensor part, arranged in a state where the magnetic flux detection directions are parallel to each other, detection centers of both the sensors and the detected part are on one reference straight line, and a mutual positional relation is fixed, and a current detection device that derives a correction coefficient to correct a change of a separation distance on the reference straight line between a target conductor and the main sensor part based on a detection value index specified based on a ratio of a detection value of the first sensor part to a detection value of the second sensor part, and a current calculation part to calculate the measurement target current based on the detection value of the main sensor part and the correction coefficient.

### INCORPORATION BY REFERENCE

The disclosure of Japanese Patent Application No. 2011-054540 filed on Mar. 11, 2011, including the specification, drawings and abstract thereof, is incorporated herein by reference in its entirety.

### BACKGROUND OF THE INVENTION

1. Field of the Invention

The present invention relates to a current detection device for detecting a measurement target current by using a sensor that is not provided with a magnetism collection core surrounding a target conductor through which the measurement target current flows, is installed separately from a detected part of the target conductor, and detects a magnetic flux in a specified magnetic flux detection direction.

2. Description of the Related Art

As a current detection device (current sensor) for detecting a current flowing through a conductor, for example, a device is known which uses a magnetic detection element, such as a Hall element, to detect a magnetic flux generated by the current and obtains a current value. The magnetic flux is generated to surround the current path according to the right-handed screw rule. Then, the detection accuracy is improved by passing the current path (conductor) through a magnetism collection core of a magnetic material formed in an annular form and collecting the magnetic flux generated by the current flowing in the current path by the core. However, recently, in response to requests for miniaturization of sensors, reduction of parts and lower costs, a coreless sensor without using a magnetism collection core surrounding the current path is put into practical use.

However, in the coreless sensor, there is a possibility that a positional shift between the current path and the sensor influences the measurement accuracy. JP-A-2010-286425 discloses a sensor unit in which reduction in measurement accuracy can be suppressed against such positional shift. This sensor unit includes a substrate having a through-hole through which a conductor as a current path passes, and four current sensors mounted on the substrate symmetrically when viewed in plane. The outputs of the four current sensors are averaged, so that the influence of the positional shift is suppressed to be low. However, in this sensor unit, the current sensors must be arranged so as to surround the periphery of the conductor, and there is a tendency that the restriction in mounting becomes large, for example, the insertion hole is provided in the substrate. Besides, there is a tendency that the apparatus scale of the sensor unit (current detection device) becomes large.

### SUMMARY OF THE INVENTION

In view of the above circumstances, it is desirable to provide a technique capable of measuring a current flowing through a conductor by a simpler structure, with high accuracy and without using a magnetism collection core surrounding a current path.

In view of the problem, a feature structure of a current detection device of the invention is such that,

in a current detection device for detecting a measurement target current by using a sensor that is not provided with a magnetism collection core surrounding a target conductor through which the measurement target current flows, is installed separately from a detected part of the target conductor, and detects a magnetic flux in a specified magnetic flux detection direction,

the sensor includes a first sensor part and a second sensor part, one of which is a main sensor part, the first sensor part and the second sensor part are arranged in a state where the magnetic flux detection directions are parallel to each other, detection centers of both the sensors and the detected part are on one reference straight line, and a mutual positional relation is fixed, and

a correction coefficient derivation part that derives a correction coefficient to correct a change of a separation distance on the reference straight line between the target conductor and the main sensor part based on a detection value index specified based on a ratio of a detection value of the first sensor part to a detection value of the second sensor part, and

a current calculation part to calculate the measurement target current based on the detection value of the main sensor part and the correction coefficient are provided.

According to the feature structure, the sensor to detect the magnetic flux includes the first sensor part and the second sensor part, one of which is the main sensor part, in the state where the mutual positional relation is fixed. The correction coefficient is derived based on the detection value index specified based on the ratio of the detection value of the first sensor part to the detection value of the second sensor part. Since the positional relation between the first sensor part and the second sensor part is fixed, the correction coefficient becomes the coefficient to correct the change of the separation distance on the reference straight line between the main sensor part as one of the first sensor part and the second sensor part and the target conductor. Accordingly, even if the separation distance between the detected part of the target conductor and the main sensor part is changed, the measurement target current can be calculated with high accuracy based on the detection value of the main sensor part and the correction coefficient. That is, at least two sensor parts including the main sensor part are provided, so that the detection error of the measurement target current due to the positional shift between the sensor part and the target conductor is suppressed, and the detection accuracy can be improved. That is, according to the feature structure, the current flowing through the conductor can be measured by the simpler structure, with high accuracy and without using a magnetism collection core surrounding a current path.

As one mode, it is preferable that the correction coefficient derivation part of the current detection device of the invention derives the correction coefficient based on an expression specified by a reference detection distance as an ideal distance on the reference straight line between the main sensor part and the detected part, an inter-sensor distance as a fixed distance on the reference straight line between the first sensor part and the second sensor part, and the detection value index. Since the reference detection distance and the inter-sensor distance are already known values according to the structure of the current detection device, they are fixed values. Accordingly, the correction coefficient derivation part can easily derive the correction coefficient by substituting the detection value index into the specified expression. Besides, as stated above, since the detection value index is specified based on the ratio of the detection value of the first sensor part to the detection value of the second sensor part, the correction coefficient can be easily derived by substituting actually measured values as actual detection values obtained by the two sensor parts. As stated above, accurate current detection can be performed with low calculation load.

The target conductor through which the measurement target current flows is not always a rod-shaped conductor having a circular sectional shape, and can be, for example, a plate-shaped conductor having a rectangular sectional shape. The way the magnetic flux is generated at the sensor installed separately from the detected part of the target conductor is different between the rod-shaped conductor and the plate-shaped conductor. Accordingly, calculation (for example, a calculation expression) of the measurement target current based on the detection value of the sensor (main sensor part) and the correction coefficient, and the component of the correction coefficient are different. In the case of a conductor, such as a flat conductor or a plate-shaped conductor, in which the target conductor has a specified width in a direction perpendicular to an extending direction of the target conductor, it is preferable to derive the correction coefficient as described below. That is, as one mode, it is preferable that the correction coefficient derivation part of the current detection device of the invention derives the correction coefficient based on an expression specified by the reference detection distance, the inter-sensor distance, the detection value index, and a conductor width as a width of the target conductor in a direction perpendicular to the reference straight line and an extension direction of the target conductor at the detected part.

The first sensor part and the second sensor part are generally installed separately from the detected part of the target conductor in a state where they are mounted on a substrate. At this time, although the first sensor part and the second sensor part may be respectively mounted on different substrates, if they are mounted on the same substrate, the number of parts can be reduced. Thus, even if the current detection accuracy is improved, the increase of the cost of the current detection device can be suppressed. Besides, if the first sensor part and the second sensor part are mounted on the same substrate, the positional relation between both the sensor parts can be fixed with high accuracy and with high resistance to aging. As a result, the current detection accuracy can be improved. As such a preferable mode, it is preferable that the first sensor part and the second sensor part of the current detection device of the invention are mounted on different surfaces of one substrate at positions overlapping with each other when viewed in a direction perpendicular to the surface of the substrate.

### BRIEF DESCRIPTION OF THE DRAWINGS

FIG. 1 is a perspective view schematically showing an arrangement example of a sensor part with respect to a rod-shaped conductor;

FIG. 2 is a sectional view schematically showing the arrangement example of the sensor part with respect to the rod-shaped conductor;

FIG. 3 is a block diagram schematically showing a structural example of a current detection device;

FIG. 4 is a view schematically showing a magnetic field generated around the rod-shaped conductor;

FIG. 5 is a flowchart schematically showing an example of a procedure of detecting a current flowing through the rod-shaped conductor;

FIG. 6 is a sectional view schematically showing an arrangement example of a sensor part with respect to a plate-shaped conductor;

FIG. 7 is a view schematically showing a magnetic field generated around the plate-shaped conductor;

FIG. 8 is a flowchart schematically showing an example of a procedure of detecting a current flowing through the plate-shaped conductor;

FIG. 9A and FIG. 9B are sectional views schematically showing another mode of an arrangement example of a sensor part with respect to a conductor;

FIG. 10 is a sectional view schematically showing another mode of an arrangement example of a sensor part with respect to a conductor;

FIG. 11 is a block diagram schematically showing an example in which a current detection device is applied to a rotating electrical machine drive device; and

FIG. 12 is a perspective view schematically showing the principle of current detection using a magnetism collection core surrounding a conductor.

### DETAILED DESCRIPTION OF THE EMBODIMENTS

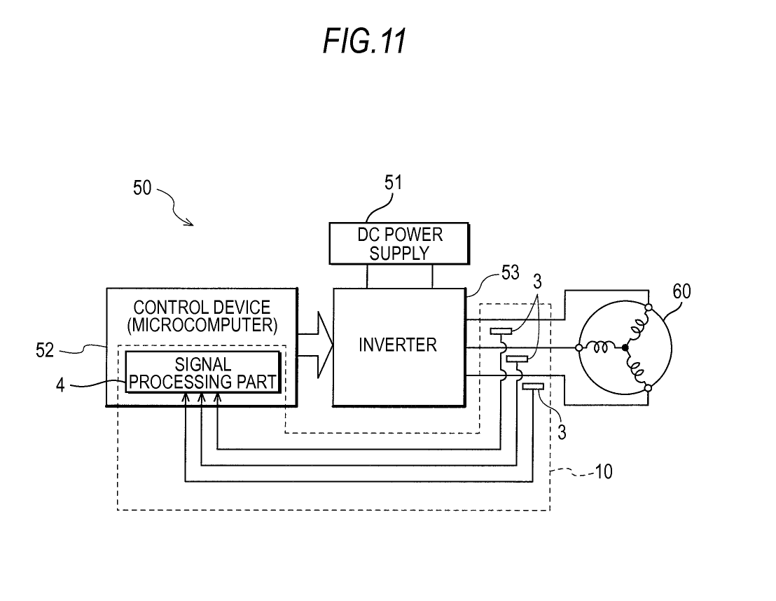

Hereinafter, embodiments of a current detection device of the invention will be described on the basis of the drawings. A current detection device 10 is applied to, for example, a drive device 50 of a rotating electrical machine 60 as shown in FIG. 11. A control device 52 of the drive device 50 controls an inverter 53 to perform power conversion between DC and AC, and controls the rotating electrical machine 60. The control device 52 is mainly formed of a microcomputer or a DSP (digital signal processor). When the rotating electrical machine 60 functions as an electric motor, the control device 52 converts DC power of a DC power supply 51 into AC power through the inverter 53, and drives the rotating electrical machine 60. Besides, when the rotating electrical machine 60 functions as an electric generator, the control device 52 rectifies generated AC power into DC power through the inverter 53 and causes the DC power supply 51 to regenerate. Sensors 3 of a current detection device 10 connect the inverter 53 and the rotating electrical machine 60 and are installed near conductors (target conductors), such as bus bars, through which currents of three phases of the U phase, the V phase and the W phase flow. That is, the sensors 3 are installed separately from current detected parts of the bus bars. For example, when the rotating electrical machine 60 functions as the electric motor, the control device 52 obtains a deviation between an actual current flowing through the bus bar and a target current, and feedback-controls a current flowing through the rotating electrical machine 60. The detection of the actual current is required for the feedback control, and the actual current is detected by the current detection device 10.

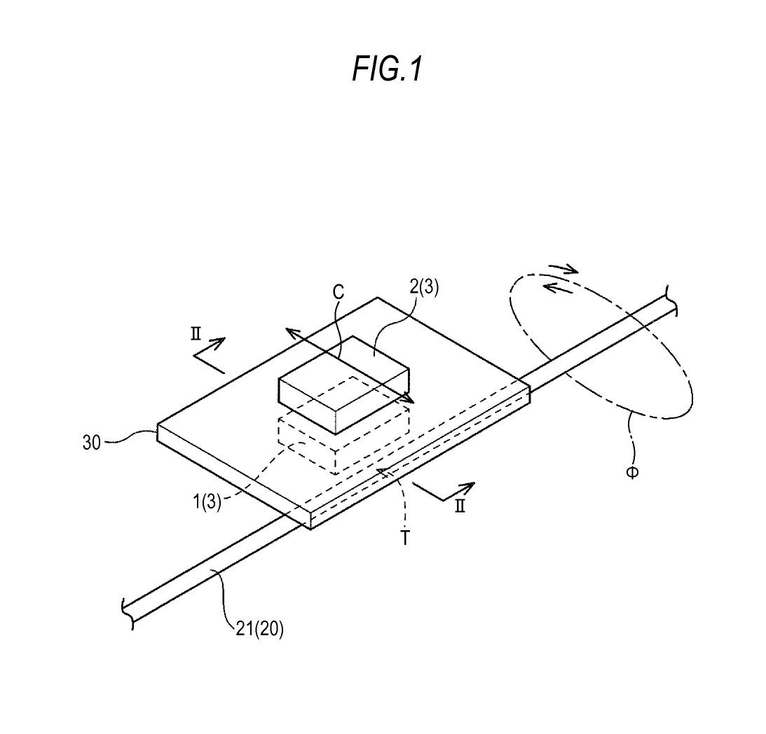

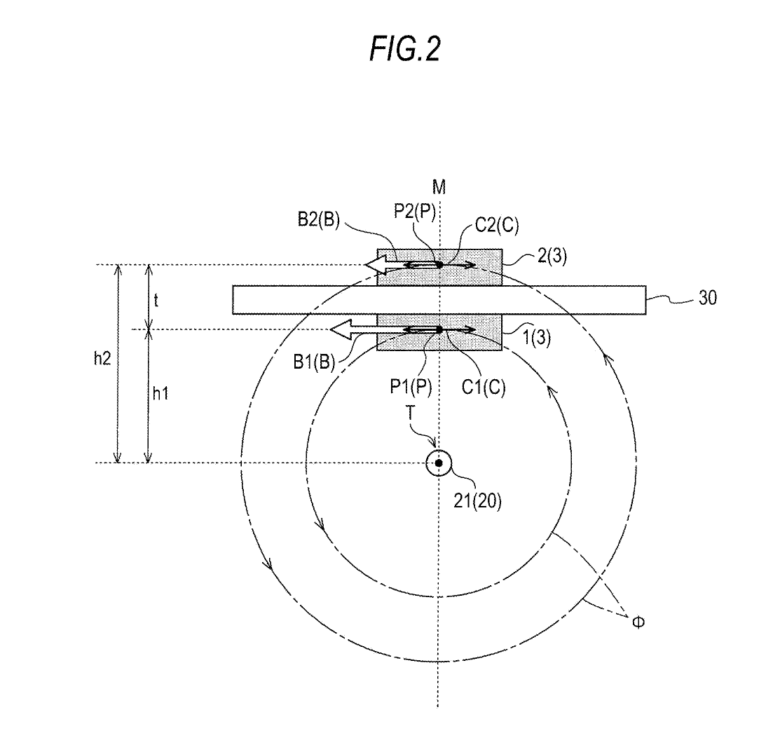

Hereinafter, the details of the current detection device will be described. FIG. 1 is a perspective view schematically showing an arrangement relation of a sensor 3 with respect to a conductor (target conductor) 20 as a measurement target through which a measurement target current to be detected by the current detection device 10 flows. Here, a rod-shaped conductor 21 having a circular sectional shape is exemplified as the conductor 20. The sensor 3 to detect a magnetic flux in a specified magnetic flux detection direction C is installed separately from a detected part T of the rod-shaped conductor 21. FIG. 2 is a sectional view of II-II of FIG. 1, that is, a sectional view at the detected part T in the direction perpendicular to an extension direction (current flowing direction) of the conductor 20. As shown in FIG. 1 and FIG. 2, the current detection device 10 of the embodiment is constructed without providing a magnetism collection core surrounding the conductor 20.

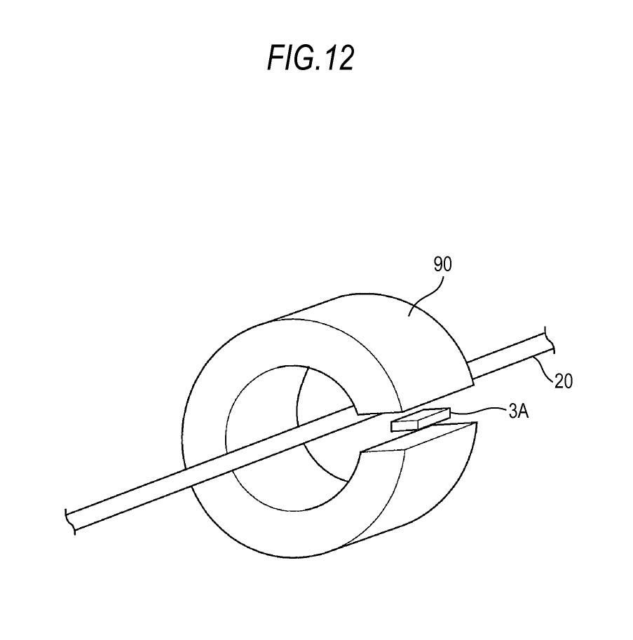

For reference, FIG. 12 shows an example of a structure including a magnetism collection core 90 surrounding a conductor 20. The magnetism collection core 90 is a magnetic core having a C-shaped section with a gap, collects the magnetic flux generated by the current flowing through the conductor 20 and guides it to a sensor 3A installed in the gap. The current detection device 10 of this embodiment is the so-called coreless current detection device for detecting the measurement target current by using the sensor 3 that is not provided with a magnetism collection core surrounding the conductor 20 through which the measurement target current flows, is installed separately from the detected part T of the conductor 20, and detects the magnetic flux in the specified magnetic flux detection direction C. Incidentally, a sensor device is also put into practical use, in which a magnetic material to change the direction of a magnetic flux or locally concentrate the magnetic flux is integrated with a hole element. However, even if the sensor device as stated above is used as the sensor 3, unless a magnetism collection core surrounding the conductor 20 is used, it is treated here as the coreless current detection device.

The current detection device 10 uses the sensor 3 to detect the magnetic field (magnetic flux density) generated by the current flowing through the conductor 20, and detects the current proportional to the magnetic flux density. However, for example, as described above, in such use as to detect the current flowing through the rotating electrical machine 60, there is a possibility that the distance between the conductor 20 and the sensor 3 varies by the vibration of the rotating electrical machine 60. Besides, when the rotating electrical machine 60 is used as a drive source for a vehicle or the like, there is a possibility that the distance between the conductor 20 and the sensor 3 varies also by the vibration of the vehicle itself. These are examples, and also when the current detection device 10 detects current other than from the rotating electrical machine 60, there is a possibility that the distance between the conductor 20 and the sensor 3 varies by various factors. When the distance between the conductor 20 and the sensor 3 varies, the intensity of the magnetic field (magnitude of the magnetic flux density) detected by the sensor 3 also varies, and accordingly, the accuracy of the current detection is reduced.

Thus, as shown in FIG. 1 and FIG. 2, the sensor 3 includes at least two sensor parts, that is, a first sensor part 1 and a second sensor part 2. One of the first sensor part 1 and the second sensor part 2 functions as a main sensor part, the detection result of which is mainly used to calculate the measurement target current. The first sensor part 1 and the second sensor part 2 are arranged in a state where magnetic flux detection directions C (C1, C2) are parallel to each other, detection centers P (P1, P2) of both the sensors and the detected part T are on one reference straight line M, and a mutual positional relation is fixed. That is, a distance (inter-sensor distance t) between the detection center P1 of the first sensor part 1 and the detection center P2 of the second sensor part 2 on the reference straight line M is fixed. In this embodiment, the first sensor part 1 and the second sensor part 2 are mounted on different surfaces of one substrate 30 at positions overlapping with each other when viewed in a direction perpendicular to the surface of the substrate 30. If the first sensor part 1 and the second sensor part 2 are constructed of electric parts such as integrated circuits (ICs), the inter-sensor distance t is specified according to the package size of the IC and the size of the substrate 30 within the range of a predetermined tolerance (size tolerance of parts and assembly tolerance).

In this embodiment, between the first sensor part 1 and the second sensor part 2, the first sensor part 1 is made the main sensor part. The current detection device 10 uses the main sensor part to detect the magnetic field (magnetic flux density) generated by the current flowing through the conductor 20, and detects the current proportional to the magnetic flux density. In FIG. 2, concentric circles of one-dot chain lines around the conductor 20 (rod-shaped conductor 21) indicate magnetic fluxes Φ generated by the current flowing from the paper front side to the back side through the conductor 20. Besides, outlined arrows at the detection center P1 of the first sensor part 1 and the detection center P2 of the second sensor part 2 indicate magnetic flux densities B (B1, B2) at the respective detection centers P. Naturally, since the magnetic field becomes high as approaching the conductor 20, and the magnetic flux density also becomes high, the main sensor part is preferably arranged in the vicinity of the conductor 20. Accordingly, in this embodiment, as shown in FIG. 2, the first sensor part 1 as the main sensor part is arranged nearer to the conductor 20 than the second sensor part 2. An ideal distance on the reference straight line M between the first sensor part 1 as the main sensor part and the detected part T of the conductor 20 is called a reference detection distance h1. Here, the reference detection distance h1 is the distance on the reference straight line M between the first sensor part 1 and the detected part T of the conductor 20 in the static state where an external force such as vibration does not act on the first sensor part 1 and the conductor 20. As described above, since the inter-sensor distance t on the reference straight line M between the first sensor part 1 and the second sensor part 2 is the fixed value, an ideal distance h2 on the reference straight line M between the second sensor part 2 and the detected part T of the conductor 20 is the sum of the reference detection distance h1 and the inter-sensor distance t.

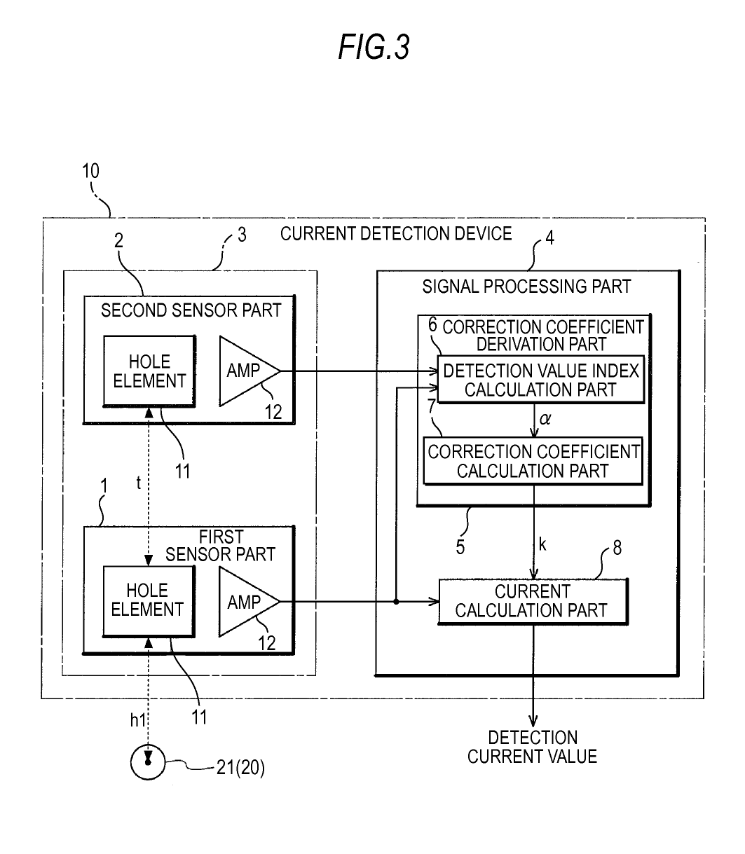

The current detection device 10 uses the sensor 3 (the first sensor part 1 and the second sensor part 2) arranged with respect to the conductor 20 and detects the measurement target current flowing through the conductor 20. Specifically, as described above by using FIG. 11 showing the application example in the rotating electrical machine 60, the current detection device 10 is constructed by cooperation of the sensor 3 with the control device 52 made of the microcomputer or the like, and detects the measurement target current. That is, the current detection device 10 is constructed by cooperation of the sensor 3 with a signal processing part 4 to calculate the detection current value by signal processing of the detection result of the sensor 3. FIG. 3 is a block diagram schematically showing a structural example of the current detection device 10 as stated above.

The sensor 3 (the first sensor part 1 and the second sensor part 2) is constructed by using various magnetic detection elements such as, for example, a hole element, an MR (magnetic resistance effect) element or an MI (magnetic impedance) element. In this embodiment, each of the first sensor part 1 and the second sensor part 2 is constructed as an IC in which a hole element 11 and a buffer amplifier 12 to perform at least impedance conversion of the output of the hole element 11 are integrated.

The signal processing part 4 includes a correction coefficient derivation part 5 and a current calculation part 8. The correction coefficient derivation part 5 includes a detection value index calculation part 6 and a correction coefficient calculation part 7. The detection value index calculation part 6 is a function part to calculate a detection value index α specified based on the ratio of the detection value of the first sensor part 1 to the detection value of the second sensor part 2. The detection value index α will be described later. The correction coefficient calculation part 7 calculates a correction coefficient k to correct a change of the separation distance (reference detection distance h1) on the reference straight line M between the conductor 20 and the main sensor part (here, the fist sensor part 1) based on the detection value index α. That is, the correction coefficient derivation part 5 including the detection value index calculation part 6 and the correction coefficient calculation part 7 derives the correction coefficient k to correct the change of the separation distance (reference detection distance h1) on the reference straight line M between the conductor 20 and the main sensor part based on the detection value index α specified based on the ratio of the detection value of the first sensor part 1 to the detection value of the second sensor part 2. The current calculation part 8 calculates the measurement target current based on the detection value of the main sensor part and the correction coefficient k, and outputs the detection current value.

As described above, since the current detection device 10 of this embodiment has the function to correct the change of the separation distance (reference detection distance h1) on the reference straight line M, and calculates the detection current value from the detection value of the main sensor part, the measurement target current can be calculated with high accuracy. Hereinafter, a derivation method of the detection value index α and the correction coefficient k will be described in detail.

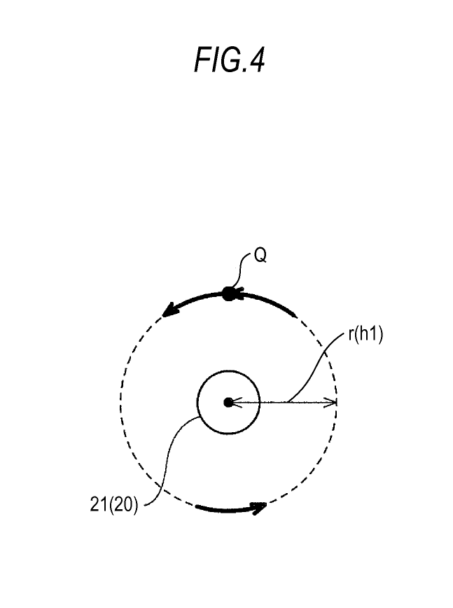

First, a magnetic field generated by a current flowing through the rod-shaped conductor 21 will be described. FIG. 4 shows the magnetic field generated by the current flowing through the rod-shaped conductor 21. The intensity H of the magnetic field generated by the current i flowing through the linear rod-shaped conductor 21, which is assumed to be infinitely long, at a point Q separated from the rod-shaped conductor 21 by a specified distance r is

H=i/2πr[A/m]=[N/Wb].

A magnetic charge of +1 [Wb], as a virtual concept, receives a force of F=1×H [N] by the magnetic field H [N/Wb] generated by the current i. The work W required to cause the magnetic charge to go around the circumference of a circle with a radius of the specified distance r as indicated by a broken line in FIG. 4 against this force is

W=1×H×2πr[J].

According to the Ampere's rule, the work required to cause the magnetic pole (magnetic charge) of magnetic charge m [Wb] to go around the conductor 20 through which the current i flows against the force received from the magnetic field generated by the current i is W[J] irrespective of the route. Accordingly, the work W is

W[J]=mi[Wb·A].

If the magnetic charge is 1 [Wb], the work W is

W[J]=1[Wb]×i[A]=1×H×2πr[J],

and the intensity H of the magnetic file is

H=i/2πr[A/m]=[N/Wb]

The magnetic flux density B[wb/m²] is obtained by multiplying the intensity H[N/Wb] of the magnetic field by permeability p[wb²/N·m²]. As shown in FIG. 1 and FIG. 2, if an air layer exits between the conductor 20 and the sensor 3, by using permeability μ₀ (=4π×10⁻⁷) in vacuum, the magnetic flux density is

B=μ₀·i/2πr[wb/m²].

The IC constituting the first sensor part 1 and the second sensor part 2 outputs, as the detection value, the voltage value proportional to the magnetic flux density B. The signal processing part 4 uses a specific calculation expression, a map or the like, and can calculate the current value based on the magnetic flux density B from the voltage value received from the first sensor part 1 and the second sensor part 2. Hereinafter, for facilitating the explanation, a description will be made on the assumption that the detection values of the first sensor part 1 and the second sensor part 2 are magnetic flux densities B.

Here, with reference to FIG. 2, the specified distance r (radius) from the conductor 20 corresponds to the reference detection distance h1 on the reference straight line M between the first sensor part 1 (main sensor part) and the detected part T of the rod-shaped conductor 21 and the distance h2 (=reference detection distance h1+inter-sensor distance t) on the reference straight line M between the second sensor part 2 and the detected part T. Accordingly, when the distance between the rod-shaped conductor 21 and the first sensor part 1 is the reference detection distance h1, a magnetic flux density B1 detected by the first sensor part 1 (main sensor part) and a magnetic flux density B2 detected by the second sensor part 2 are respectively given by the following expressions (1) and (2).

$$\begin{matrix}[ Mathematical Formula 1 ] & \\ B 1 = \frac{{μ}_{0}}{2 π \cdot h 1} i , & ( 1 ) \\ B 2 = \frac{{μ}_{0}}{2 π \cdot h 2} i = \frac{{μ}_{0}}{2 π \cdot ( h 1 + t )} i & ( 2 )\end{matrix}$$

Here, when the distance between the rod-shaped conductor 21 and the first sensor part 1 is the reference detection distance h1, the ratio (ratio of detection values) of the magnetic flux density B1 detected by the first sensor part 1 (main sensor part) to the magnetic flux density B2 detected by the second sensor part 2 is given by the following expression (3). As is apparent from the expression (3), this ratio is the value determined by only the distance between the rod-shaped conductor 21 and the first sensor part 1, which can change, and the inter-sensor distance t as the fixed value, and this ratio is made a detection value index α. Incidentally, the value of the detection value index α at the time when the distance between the rod-shaped conductor 21 and the first sensor part 1 is the reference detection distance h1 is called an initial value (ideal value) α₀ of the detection value index α.

$$\begin{matrix}[ Mathematical Formula 2 ] & \\ α = \frac{B 2}{B 1} = \frac{h 1}{h 1 + t} = {α}_{0} & ( 3 )\end{matrix}$$

Here, if the distance between the rod-shaped conductor 21 and the first sensor part 1 becomes larger than the reference detection distance h1 by Δh on the reference straight line M, since the inter-sensor distance t is the fixed value, the magnetic flux densities B1 and B2 at both the sensor parts respectively become the magnetic flux densities B1 and B2 given by the following expressions (4) and (5), and the detection value index α becomes the value given by the following expression (6). Since the detection value index α is the value based on actually measured values which are the actual detection values of the first sensor part 1 and the second sensor part 2, hereinafter, this is called an actually measured value αₕ of the detection value index α. Incidentally, by substituting a negative value into the variation Δh, the expression (4) to the expression (6) can be applied also to the case where the distance between the rod-shaped conductor 21 and the first sensor part 1 becomes short.

$$\begin{matrix}[ Mathematical Formula 3 ] & \\ B 1 = \frac{{μ}_{0}}{2 π \cdot ( h 1 + Δ h )} i , & ( 4 ) \\ B 2 = \frac{{μ}_{0}}{2 π \cdot ( ( h 1 + Δ h ) + t )} i & ( 5 ) \\ [ Mathematical Formula 4 ] & \\ α = \frac{B 2}{B 1} = \frac{h 1 + Δ h}{( h 1 + Δ h ) + t} = {α}_{h} & ( 6 )\end{matrix}$$

Since the first sensor part 1 and the second sensor part 2 are arranged so that the inter-sensor distance t is “t≠0”, if the distance between the rod-shaped conductor 21 and the first sensor part 1 is changed, the initial value (ideal value) α₀ of the detection value index α and the actually measured value αₕ become different values. Accordingly, for example, the signal processing part 4 can determine the presence or absence of the positional shift between the rod-shaped conductor 21 and the sensor 3 by comparing the initial value (ideal value) α₀ of the detection value index α stored in the program memory or the parameter memory of the microcomputer with the actually measured value αₕ of the detection value index a calculated based on the actually measured values of the first sensor part 1 and the second sensor part 2. Besides, the variation Δh of the distance between the rod-shaped conductor 21 and the first sensor part 1 is given by the following expression (7) by modifying the expression (6).

$$\begin{matrix}[ Mathematical Formula 5 ] & \\ {α}_{h} ( h 1 + Δ h + t ) = h 1 + Δ h \\ Δ h ( {α}_{h} - 1 ) = h 1 - {α}_{h} ( h 1 + t ) \\ Δ h = \frac{{α}_{h} ( h 1 + t ) - h 1}{1 - {α}_{h}} & ( 7 )\end{matrix}$$

If the distance between the rod-shaped conductor 21 and the first sensor part 1 (main sensor part) increases or decreases with respect to the reference detection distance h1, as represented by the following expression (8), the magnetic flux density B at the time when the distance between the rod-shaped conductor 21 and the first sensor part 1 is the reference detection distance h1 can be obtained by multiplying the correction coefficient k to the magnetic flux density B1 as the actually measured value obtained by the first sensor part 1 (main sensor part). That is, the variation of the detection value of the main sensor part due to the variation of the reference detection distance h1 can be corrected by using the correction coefficient k. The correction coefficient k is defined as represented by the following expression (9) by modifying the following expression (8).

$$\begin{matrix}[ Mathematical Formula 6 ] & \\ B 1 = \frac{{μ}_{0}}{2 π \cdot ( h 1 + Δ h )} i \times k = \frac{{μ}_{0}}{2 π \cdot h 1} i & ( 8 ) \\ [ Mathematical Formula 7 ] & \\ k = \frac{h 1 + Δ h}{h 1} & ( 9 )\end{matrix}$$

Incidentally, as represented by the expression (7), a value obtained based on the reference detection distance h1, the inter-sensor distance t, and the actually measured value αₕ of the detection value index α calculated by using the actually measured values of both the sensor parts are used as the variation Δh of the distance between the rod-shaped conductor 21 and the first sensor part 1. That is, the correction coefficient calculation part 7 calculates the correction coefficient k to correct the change (variation Δh) of the separation distance (reference detection distance h1) on the reference straight line M between the conductor 20 and the main sensor part (here, the first sensor part 1) based on the detection value index α. The magnetic flux density B1 detected by the first sensor part 1 is determined from the expression (8) and the expression (9). Based on the magnetic flux density B1, the current calculation part 8 can calculate the current i flowing through the rod-shaped conductor 21, that is, the measurement target current. That is, the current calculation part 8 calculates the measurement target current based on the detection value of the main sensor part and the correction coefficient k and outputs the detection current value.

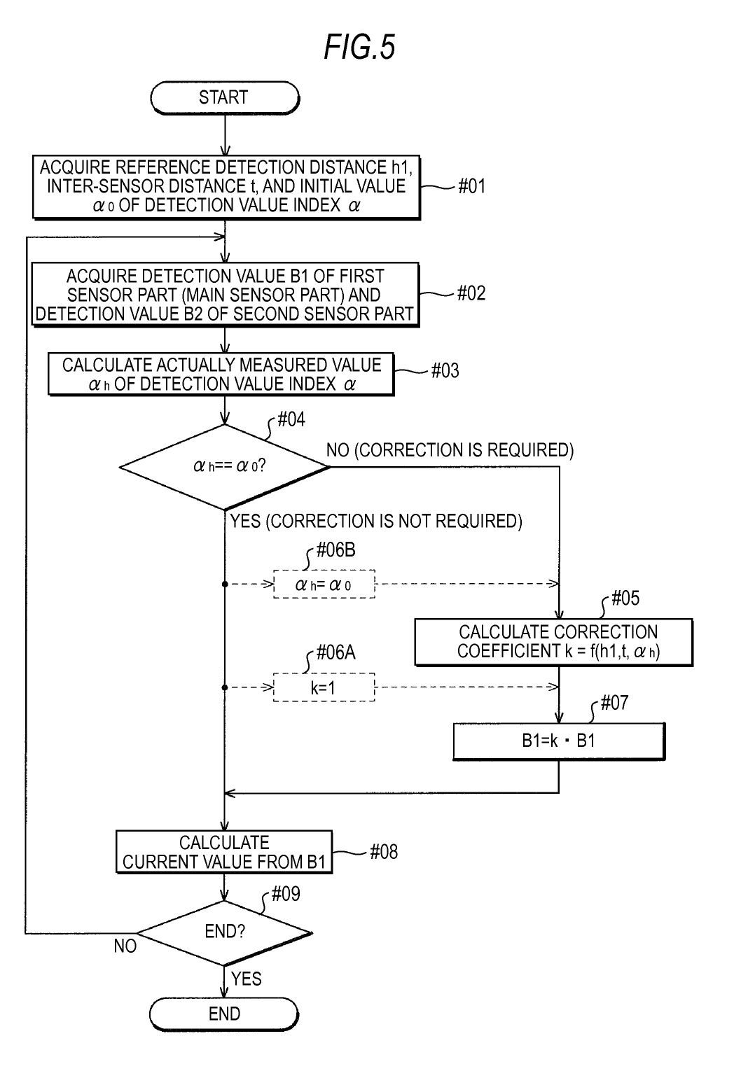

As described above while exemplifying FIG. 3, the signal processing part 4 of the current detection device 10 is mainly constructed of the arithmetic logic unit such as the microcomputer. Although the magnetic flux density B (voltage value proportional to the magnetic flux density B) is detected by the sensor 3, the value of the current based on the detected magnetic flux density B (B1, B2) is calculated by cooperation of, for example, the hardware of the microcomputer and the program (software) executed on the hardware. Hereinafter, an example of the procedure of detecting the current by calculation performed by the microcomputer as stated above will be described by use of a flowchart of FIG. 5. Incidentally, contents described above are appropriately omitted.

First, as an initialization step, the reference detection distance h1, the inter-sensor distance t, and the initial value α₀ of the detection value index α are acquired from the program memory or the parameter memory, and are stored in the inner register of the microcomputer (#01). Since these values are fixed values, they are not required to be acquired each time the current value is calculated. While the repeatedly executed current detection process continues, the process from step #02 as the next process of the initialization step #01 to end determination step #09 is repeated. A frequency of current detection, that is, a current detection period is specified based on the requirement specifications of an apparatus to perform control using a current value of a control target, such as, for example, the drive device 50 of the rotating electrical machine 60 shown in FIG. 11, and is set in the program or the like. The process from the step #02 to the step #09 are executed within the required current detection period.

At the beginning of the repeatedly executed current detection process, the detection value (magnetic flux density B1) of the first sensor part 1 and the detection value (magnetic flux density B2) of the second sensor part 2 are acquired (detection value acquisition step #02). If the first sensor part 1 and the second sensor part 2 output detection values as analog data, it is converted into digital data by, for example, an A/D converter incorporated in the microcomputer and is stored in the inner register. Of course, the A/D converter may be a separate device from the microcomputer. Next, the actually measured value αₕ of the detection value index α is calculated by using the detection values of the first sensor part 1 and the second sensor part 2, and is stored in the inner register (detection value index calculation step #03).

Next, a determination is made as to whether or not the initial value α₀ of the detection value index α acquired at the initialization step #01 coincides with the actually measured value αₕ of the detection value index α calculated at the detection value index calculation step #03 (positional shift determination step #04). As described above, if the positional shift occurs between the conductor 20 and the sensor 3, the values of both the detection value indexes α are different from each other, and accordingly, the presence or absence of the positional shift can be determined. Incidentally, at this time, a determination is preferably made in view of the error of the analog signal processing in the sensor 3, rounding error at the A/D conversion, rounding error at the calculation of the actually measured value αₕ of the detection value index α, and the like. For example, a determination is preferably made that both coincide with each other if the difference Δα between the initial value α₀ and the actually measured value αₕ is a specified determination threshold or less.

At the positional shift determination step #04, if the determination is made that the positional shift occurs, since this is equivalent to the determination that “correction is required”, next, the correction coefficient k is calculated and is stored in the inner register (correction coefficient calculation step #05). As described above while using the expression (7) to the expression (9), the correction coefficient k is the function f (h1, t, αₕ) of the reference detection distance h1, the inter-sensor distance t, and the actually measured value αₕ of the detection value index α. At the step #01 to the step #03, the correction coefficient k is derived by using these values stored in the inner register. When the correction coefficient k is derived, as represented by the expression (8), the detection value (magnetic flux density B1) of the main sensor part (here, the first sensor part 1) is corrected by using the correction coefficient k, and is stored in the inner register (detection value correction step #07). The value of the measurement target current is calculated by using the corrected detection value (magnetic flux density B1) (current value calculation step #08).

At the positional shift determination step #04, if the determination is made that the initial value α₀ and the actually measured value αₕ coincide with each other, the positional shift does not occur, and this is equivalent to the determination that “correction is not required”. Accordingly, the correction coefficient calculation step #05 and the detection value correction step #07 are skipped, advance is made to the current value calculation step #08, and the value of the measurement target current is calculated by using the uncorrected detection value (magnetic flux density B1). However, in the case of “α₀=αₕ”, since the variation Δh becomes “0” in the expression (7), the correction coefficient k becomes “1” in the expression (9). Accordingly, the correction coefficient calculation step #05 and the detection value correction step #07 may be always executed without providing the positional shift determination step #04. However, as stated above, it is preferable that if the difference Δα between the initial value α₀ and the actually measured value αₕ is the specified determination threshold or less, the determination is made that both coincide with each other. Accordingly, at the positional shift determination step #04, even if the determination is made that correction is not required, there is a case where the difference Δα between the initial value α₀ and the actually measured value αₕ is not “0”, and the variation Δh in the expression (7) does not become “0”.

Thus, as shown in FIG. 5, the positional shift determination step #04 is preferably provided. Incidentally, correction coefficient setting step #06A is provided at which if the determination is made at the positional shift determination step #04 that “correction is not required”, the correction coefficient k is set to “1”, and the detection value correction step #07 may be executed after this correction coefficient setting step #06A. Besides, detection value index setting step #06B is provided at which if the determination is made at the positional shift determination step #04 that “correction is not required”, the actually measured value αₕ of the detection value index α is set to the initial value α₀, and the correction coefficient calculation step #05 and the detection value correction step #07 may be executed after this detection value index setting step #06B.

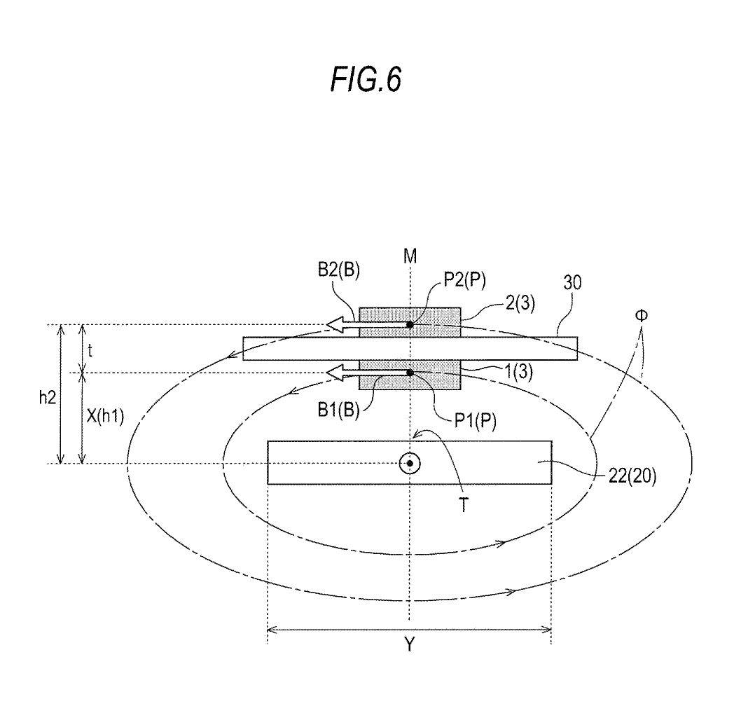

In the above, the current detection device 10 of the invention is described while using the example in which the measurement target current flowing through the rod-shaped conductor 21 is detected. However, the conductor 20 is not limited to the rod-shaped conductor 21 as stated above. For example, in the drive device 50 of the rotating electrical machine 60 shown in FIG. 11, there is a case where a large current flows through the conductor 20, and in that case, the conductor 20 having a large cross-sectional area is required to be used. At this time, in view of the installation efficiency and wiring efficiency, there is a case where a bus bar as the conductor 20 is formed into a flat plate shape having a rectangular sectional shape as shown in FIG. 6. A magnetic field generated by a current flowing through a plate-shaped conductor 22 as stated above is different from a magnetic field formed by a current flowing through the rod-shaped conductor 21.

Strictly, based on the Biot-Savart law, a magnetic field generated by a current flowing through a minute area of the cross section of the plate-shaped conductor 22 is obtained, a vector component of the magnetic field in a magnetic flux detection direction C is obtained at a detection center P of the sensor 3, and that is required to be integrated over all the cross section. However, since this is very troublesome, an approximate expression is preferably used in view of practicability. Incidentally, the Ampere's law stated in the description of the rod-shaped conductor 21 is equal to the integration result based on the Biot-Savart law. Accordingly, in the following description of the approximate expression in view of practicability, the description is made while using the magnetic field derived from the Ampere's law.

As described above with reference to FIG. 4, the intensity H of the magnetic field generated by the current i flowing through the rod-shaped conductor 21 at the point Q separated from the rod-shaped conductor 21 by the specified distance r is

H=i/2πr[A/m]=[N/Wb].

The work required to cause a magnetic pole (magnetic charge) with a magnetic charge of 1 [Wb] to go around the conductor 20, through which the current i flows, against the force received from the magnetic field generated by the current i is irrespective of the path and is

W[J]=1[Wb]×i [A]=1×H×2πr [Wb·A].

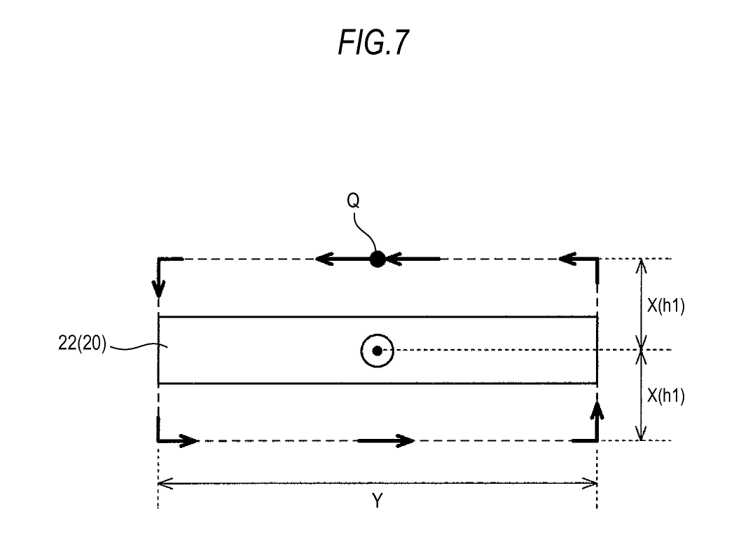

Here, as shown in FIG. 7, consideration is given to the work W required to cause a magnetic pole (magnetic charge) with a magnetic charge of 1 [Wb] to go around the plate-shaped conductor 22, through which the current i flows, from point Q through a rectangular path against the force received from the magnetic field generated by the current i. The path “2πr” on the circumference shown in FIG. 4 is replaced by the path “2(Y+2X)” on the rectangular, and the work W becomes

W[J]=1[Wb]×i[A]=1×H×2(Y+2X)[Wb·A].

When the intensity H of the magnetic field is obtained from here,

H=i/2(Y+2X)[A/m]=[N/Wb].

Similarly to the rod-shaped conductor 21, as shown in FIG. 6, if an air layer exists between the plate-shaped conductor 22 and the sensor 3, permeability μ₀ (=4π×10⁻⁷)[wb²/N·m²] in vacuum is used, and the magnetic flux density B [wb/m²] is

B=μ₀·i/2(Y+2X)[wb/m²].

If the width (conductor width Y) of the plate-shaped conductor 22 is several or more times larger than the distance X between the center of the plate-shaped conductor 22 and the point Q, the approximation can be made in this way. Incidentally, as described below with reference to FIG. 6, the point Q corresponds to the detection center P of the sensor 3, and the distance X between the center of the plate-shaped conductor 22 and the point Q corresponds to the reference detection distance h1.

As shown in FIG. 6, also with respect to the plate-shaped conductor 22, the first sensor part 1 and the second sensor part 2 are arranged while the first sensor part 1 is made the main sensor part. The current detection device 10 uses the main sensor part to detect the magnetic field H (magnetic flux density B) generated by the current flowing through the conductor 20, and detects the current proportional to the magnetic flux density B. Similarly to FIG. 2, an ellipse of a one-dot chain line indicates the magnetic flux Φ generated by the current flowing from the paper front side to the back side through the plate-shaped conductor 22. Besides, outlined arrows at the detection center P1 of the first sensor part 1 and the detection center P2 of the second sensor part 2 indicate magnetic flux densities B (B1, B2) at the respective detection centers P. Similarly to the rod-shaped conductor 21, the reference detection distance h1 is an ideal distance on the reference straight line M between the detection center P1 of the first sensor part 1 as the main sensor part and the detected part T of the plate-shaped conductor 22. Besides, the inter-sensor distance t on the reference straight line M, and the distance h2 on the reference straight line M between the detection center P2 of the second sensor part 2 and the detected part T of the plate-shaped conductor 22 are also the same. When the width (conductor width) of the plate-shaped conductor 22 is Y, the magnetic flux density B1 detected by the first sensor part 1 (main sensor part) and the magnetic flux density B2 detected by the second sensor part 2 are respectively given by the following expressions (10) and (11). Incidentally, the conductor width Y is the width of the conductor 20 in the direction perpendicular to the extension direction of the conductor 20 at the detected part T and the reference straight line M.

$$\begin{matrix}[ Mathematical Formula 8 ] & \\ B 1 = \frac{{μ}_{0}}{2 ( Y + 2 \cdot h 1 )} i , & ( 10 ) \\ B 2 = \frac{{μ}_{0}}{2 ( Y + 2 \cdot h 2 )} i = \frac{{μ}_{0}}{2 ( Y + 2 ( h 1 + t ) )} i & ( 11 )\end{matrix}$$

From the expression (10) and the expression (11), the detection value index α, especially the initial value (ideal value) α₀ of the detection value index α when the distance between the plate-shaped conductor 22 and the first sensor part 1 is the reference detection distance h1 is given by the following expression (12).

$$\begin{matrix}[ Mathematical Formula 9 ] & \\ α = \frac{B 2}{B 1} = \frac{Y + 2 \cdot h 1}{Y + 2 ( h 1 + t )} = {α}_{0} & ( 12 )\end{matrix}$$

Here, if the distance between the plate-shaped conductor 22 and the first sensor part 1 becomes larger than the reference detection distance h1 on the reference straight line M by Δh, the magnetic flux densities B1 and B2 at both the sensor parts become the magnetic flux densities B1 and B2 given by the following expressions (13) and (14), and the detection value index a becomes the actually measured value αₕ given by the following expression (15). Incidentally, similarly to the rod-shaped conductor 21, by substituting a negative value into the variation Δh, the expressions (13) to (15) can also be applied to the case where the distance between the plate-shaped conductor 22 and the first sensor part 1 becomes short.

$$\begin{matrix}[ Mathematical Formula 10 ] & \\ B 1 = \frac{{μ}_{0}}{2 ( Y + 2 ( h 1 + Δ h ) )} i , & ( 13 ) \\ B 2 = \frac{{μ}_{0}}{2 ( Y + 2 ( ( h 1 + Δ h ) + t ) )} i & ( 14 ) \\ [ Mathematical Formula 11 ] & \\ α = \frac{B 2}{B 1} = \frac{Y + 2 ( h 1 + Δ h )}{Y + 2 ( ( h 1 + Δ h ) + t )} = {α}_{h} & ( 15 )\end{matrix}$$

The variation Δh of the distance between the plate-shaped conductor 22 and the first sensor part 1 is given by the following expression (16) by modifying the expression (15).

$$\begin{matrix}[ Mathematical Formula 12 ] & \\ {α}_{h} ( Y + 2 ( ( h 1 + Δ h ) + t ) ) = Y + 2 ( h 1 + Δ h ) \\ Δ h \cdot 2 \cdot ( {α}_{h} - 1 ) = Y + 2 \cdot h 1 - {α}_{h} ( Y + 2 \cdot h 1 + 2 \cdot t ) \\ Δ h = \frac{{α}_{h} ( 0.5 Y + h 1 + t ) - h 1 - 0.5 Y}{1 - {α}_{h}} & ( 16 )\end{matrix}$$

When the distance between the plate-shaped conductor 22 and the first sensor part 1 (main sensor part) increases or decreases with respect to the reference detection distance h1, as represented by the following expression (17), by multiplying the correction coefficient k to the magnetic flux density B1 as the actually measured value obtained by the first sensor part 1 (main sensor part), the magnetic flux can be corrected to the magnetic flux density B1 at the time when the distance between the plate-shaped conductor 22 and the first sensor part 1 is the reference detection distance h1.

$$\begin{matrix}[ Mathematical Formula 13 ] & \\ B 1 = \frac{{μ}_{0}}{2 ( Y + 2 \cdot h 1 )} i \times k = \frac{{μ}_{0}}{2 ( Y + 2 \cdot h 1 )} i & ( 17 )\end{matrix}$$

By modifying the expression (17), the correction coefficient k is given by the following expression (18). Incidentally, as represented by the expression (16), the value obtained based on the reference detection distance h1, the inter-sensor distance t, and the actually measured value αₕ of the detection value index α calculated by using actually measured values of both the sensor parts is used the variation Δh of the distance between the plate-shaped conductor 22 and the first sensor part 1.

$$\begin{matrix}[ Mathematical Formula 14 ] & \\ k = \frac{Y + 2 ( h 1 + Δ h )}{Y + 2 \cdot h 1} & ( 18 )\end{matrix}$$

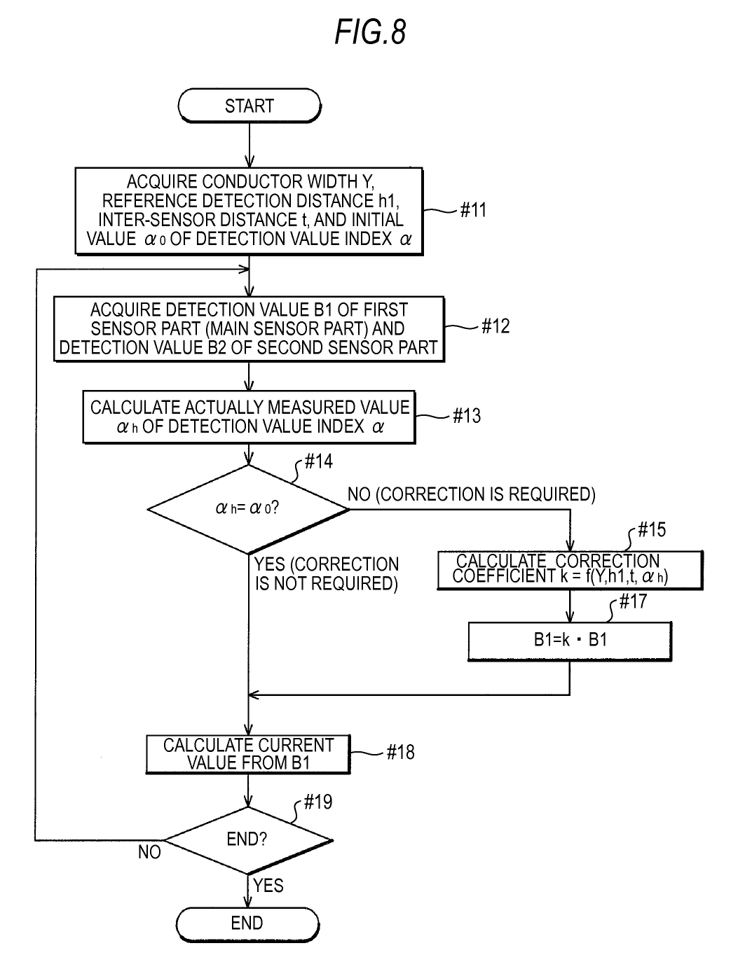

As described above, even if the target conductor through which the measurement target current flows is the plate-shaped conductor 22, the preferable current detection device 10 can be constructed. Incidentally, since the function part of the current detection device 10 described with reference to FIG. 3 is the same as that of the rod-shaped conductor 21, the description thereof is omitted. Incidentally, although the procedure of detecting the current by calculation performed by the microcomputer is basically the same as that of the rod-shaped conductor 21, different points will be mainly supplementarily described with reference to a flowchart of FIG. 8.

First, at initialization step #11, the conductor width Y, together with the reference detection distance h1, the inter-sensor distance t and the initial value α₀ of the detection value index α, is acquired from the program memory or the parameter memory and is stored in the inner register. Then, at the beginning of the repeatedly executed current detection process, the detection value (magnetic flux density B1) of the first sensor part 1 and the detection value (magnetic flux density B2) of the second sensor part 2 are acquired (detection value acquisition step #12). Next, the actually measured value αₕ of the detection value index α is calculated using the detection values of the first sensor part 1 and the second sensor part 2, and is stored in the inner register (detection value index calculation step #13). Next, a determination is made as to whether or not the initial value α₀ of the detection value index α acquired at the initialization step #11 coincides with the actually measured value αₕ of the detection value index α calculated at the detection value index calculation step #13 (positional shift determination step #14).

At the positional shift determination step #14, if the determination is made that the positional shift occurs (correction is required), the correction coefficient k is calculated (correction coefficient calculation step #15). As described above with reference to the expressions (16) to (18), the correction coefficient k is the function f(Y, h1, t, αₕ) of the conductor width Y, the reference detection distance h1, the inter-sensor distance t, and the actually measured value αₕ of the detection value index α. The correction coefficient k is derived by using these values stored in the inner register at the step #11 to the step #13. When the correction coefficient k is derived, as represented in the expression (17), the detection value (magnetic flux density B1) of the main sensor part (here, the first sensor part 1) is corrected by using the correction coefficient k (detection value correction step #17). Then, the value of the measurement target current is calculated by using the corrected detection value (magnetic flux density B1) (current value calculation step #18).

### Other Embodiments

(1) In the above, while the rod-shaped conductor 21 and the plate-shaped conductor 22 are exemplified, the description is made that the current detection device 10 of the invention can measure the current flowing through the conductor 20 by the simple structure and with high accuracy. If the above description is considered, even if the sectional shape of the conductor 20 becomes another shape such as an ellipse, the invention can be applied by establishing expressions of the intensity H of the magnetic field at the detection center P of the main sensor and the magnetic flux density B. Accordingly, the invention is not limited to the conductor 20 having the foregoing sectional shape, but can be applied to the conductors 20 having various sectional shapes. Besides, in the above description, although the magnetic flux density B of the plate-shaped conductor 22 is defined by the approximate expression, the magnetic flux density may be strictly defined using the integration or the like without using the approximation.

(2) In the description, the example is described in which the correction coefficient k is obtained based on the calculation expression. However, no limitation is made to the mode of obtaining the correction coefficient k by using the calculation expression, and the correction coefficient may be set by referring to a map (correction coefficient map) defining the relation between the actually measured value αₕ of the detection value index α and the correction coefficient k. The map as stated above is preferably prepared by experiments or simulation in advance. Especially, with respect to the conductor 20 in which the expression for calculating the magnetic field H generated around the conductor 20 from the sectional shape becomes complicated, there is a possibility that it is difficult to obtain the correction coefficient k by each calculation, or the calculation load becomes high. In the case of the conductor 20 as stated above, if the correction coefficient k is set by referring to the previously prepared correction coefficient map, the calculation load can be suppressed, and this is preferable.

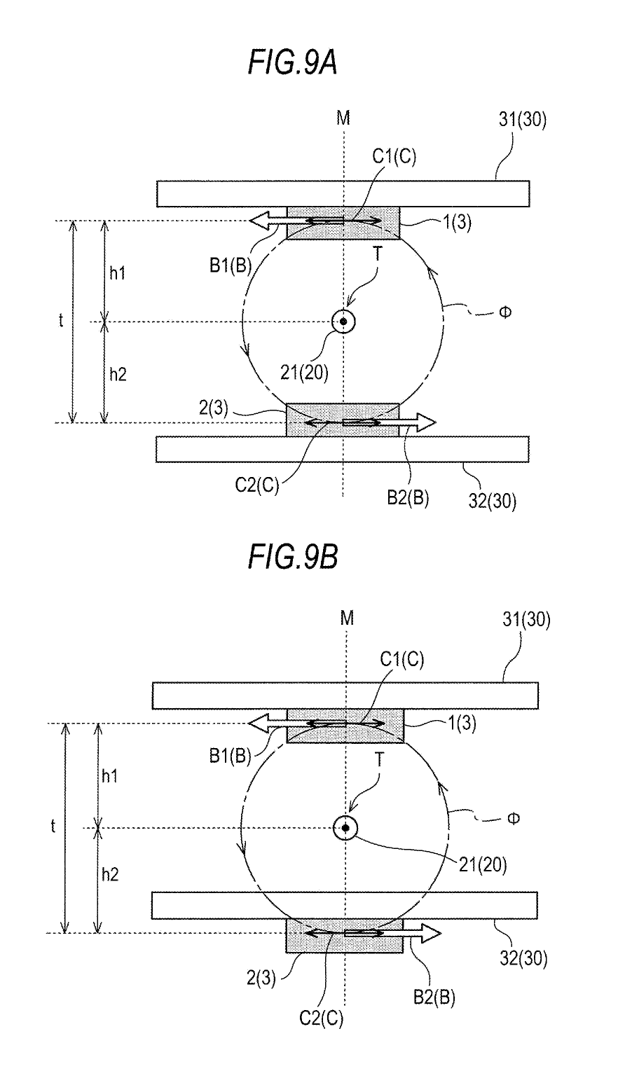

(3) In the description, the example is description in which the first sensor part 1 and the second sensor part 2 are mounted on the different surfaces of the one substrate 30 at the positions overlapping with each other when viewed in the direction perpendicular to the surface of the substrate 30. However, the first sensor part 1 and the second sensor part 2 may be separately mounted on plural substrates as long as they are arranged in the state where the magnetic flux detection directions C are parallel to each other, the detection centers P (p1, P2) of both the sensors and the detected part T are on one reference straight line M, and the mutual positional relation is fixed. For example, as shown in FIG. 9A, the first sensor part 1 and the second sensor part 2 may be mounted on substrates 30 (31, 32) opposite to each other through the conductor 20. Besides, also in this case, no limitation is made to the case where the first sensor part 1 and the second sensor part 2 are opposite to each other through the conductor 20 and are mounted on the respective substrates 30. As shown in FIG. 9B, the first sensor part 1 and the second sensor part 2 may be mounted in the same direction on the substrates 30 (31, 32) opposite to each other through the conductor 20.

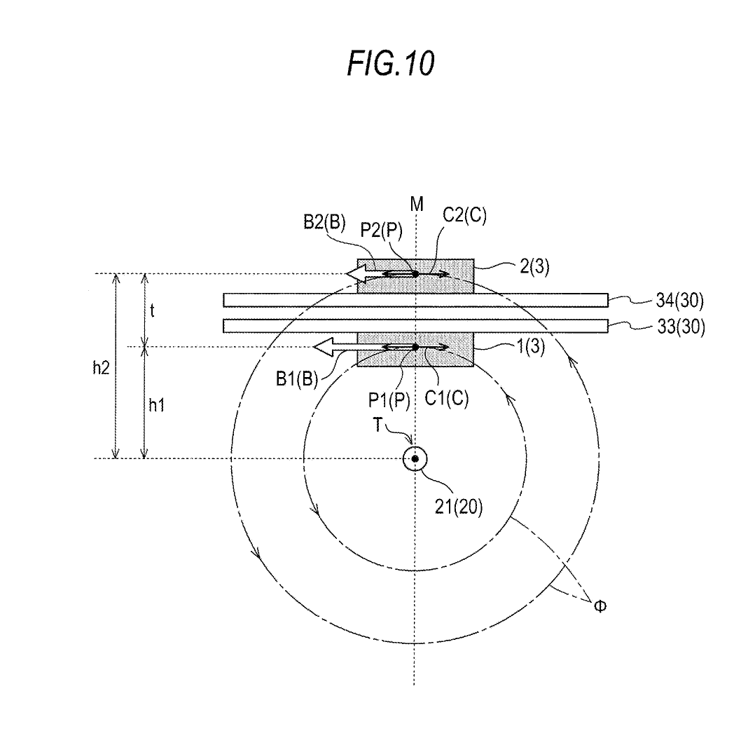

(4) Besides, when the first sensor part 1 and the second sensor part 2 are separately mounted on the plural substrates 31 and 32, no limitation is made to the mode in which the substrate 31 and the substrate 32 are arranged across the conductor 20 as shown in FIG. 9A and FIG. 9B. For example, as shown in FIG. 10, separate substrates 33 and 34 are provided at the same side with respect to the conductor 20, and the first sensor part 1 may be mounted on one of them, and the second sensor part 2 may be mounted on the other. Although FIG. 10 shows the example in which the substrate 33 and the substrate 34 are arranged back to back, that is, surfaces on which the sensors 3 are not mounted face each other, another arrangement may be naturally adopted. For example, the substrates 33 and 34 may be arranged so that the surfaces on which the sensors 3 are mounted face each other, or may be arranged so that the surface on which the sensor 3 is not mounted and the surface on which the sensor 3 is mounted face each other, that is, they are directed in the same direction. Besides, when the substrate 33 and the substrate 34 are arranged back to back, although a gap is provided between both the substrates in the example shown in FIG. 10, no limitation is made to this mode, and they may be arranged so that the surfaces on which the sensors 3 are not mounted come in close contact with each other.

(5) In the description, the case is exemplified in which the detection value index α as the ratio of the detection value of the first sensor part 1 and the detection value of the second sensor part 2 is defined by B2/B1. However, since the detection value index α has only to be the ratio of the detection value of the first sensor part 1 and the detection value of the second sensor part 2, B1/B2 may be adopted. Of course, in this case, although the expressions of the correction coefficient k and the like become different from those of the foregoing example, since those skilled in the art can easily derive them from the above description, the detailed description is omitted.

As described above, according to the invention, the current flowing through the conductor can be easily measured by the simple structure, with high accuracy, and without using a magnetism collection core around a current path.

The invention can be applied to a current detection device, a current detection method and a program, in which a magnetism collection core surrounding a target conductor through which a measurement target current flows is not provided, and the measurement target current is detected by using a sensor that is installed separately from a detected part of the target conductor and detects a magnetic flux in a specified magnetic flux detection direction. Besides, the invention can also be applied to a drive device for controlling a rotating electrical machine or the like by using the current detection device or the current detection method as stated above and using the value of the detected current.

What is claimed is:

1. A current detection device for detecting a measurement target current by using a sensor that is not provided with a magnetism collection core surrounding a target conductor through which the measurement target current flows, is installed separately from a detected part of the target conductor, and detects a magnetic flux in a specified magnetic flux detection direction, wherein
the sensor includes a first sensor part and a second sensor part, one of which is a main sensor part,
the first sensor part and the second sensor part are arranged in a state where the magnetic flux detection directions are parallel to each other, detection centers of both the sensors and the detected part are on one reference straight line, and a mutual positional relation is fixed, and
the current detection device includes
a correction coefficient derivation part that derives a correction coefficient to correct a change of a separation distance on the reference straight line between the target conductor and the main sensor part based on a detection value index specified based on a ratio of a detection value of the first sensor part to a detection value of the second sensor part, and
a current calculation part to calculate the measurement target current based on the detection value of the main sensor part and the correction coefficient.

2. The current detection device according to claim 1, wherein the correction coefficient derivation part derives the correction coefficient based on an expression specified by a reference detection distance as an ideal distance on the reference straight line between the main sensor part and the detected part, an inter-sensor distance as a fixed distance on the reference straight line between the first sensor part and the second sensor part, and the detection value index.

3. The current detection device according to claim 2, wherein the correction coefficient derivation part derives the correction coefficient based on an expression specified by the reference detection distance, the inter-sensor distance, the detection value index, and a conductor width as a width of the target conductor in a direction perpendicular to the reference straight line and an extension direction of the target conductor at the detected part.

4. The current detection device according to claim 3, wherein the first sensor part and the second sensor part are mounted on different surfaces of one substrate at positions overlapping with each other when viewed in a direction perpendicular to the surface of the substrate.

5. The current detection device according to claim 1, wherein the first sensor part and the second sensor part are mounted on different surfaces of one substrate at positions overlapping with each other when viewed in a direction perpendicular to the surface of the substrate.

6. The current detection device according to claim 2, wherein the first sensor part and the second sensor part are mounted on different surfaces of one substrate at positions overlapping with each other when viewed in a direction perpendicular to the surface of the substrate.
